(19) United States
(12) Patent Application Publication
(10) Pub. No.: US 2026/0053039 A1
(43) Pub. Date: Feb. 19, 2026

(54) METHOD FOR FORMING BUMP STRUCTURE

(71) Applicant: Taiwan Semiconductor Manufacturing Company, Ltd., Hsinchu (TW)

(72) Inventors: Li-Guo LEE, Hsinchu (TW); Yi-Chen LIU, Zhudong Township (TW); Yung-Sheng LIU, Hsinchu City (TW); Yi-Jen LAI, Hsinchu City (TW); Chun-Jen CHEN, Jhubei City (TW); Hsi-Kuei CHENG, Zhubei City (TW)

(21) Appl. No.: 19/366,770

(22) Filed: Oct. 23, 2025

Related U.S. Application Data
(63) Continuation of application No. 15/725,535, filed on Oct. 5, 2017.
Application No. 15/725,535 is a division of application No. 14/208,871, filed on Mar. 13, 2014, now abandoned.

(51) Int. Cl. H01L 23/00

(52) U.S. Cl. CPC H01L 24/13; H01L 24/03; H01L 24/05; H01L 24/11; H01L 24/81; H01L 2224/0345; H01L 2224/0361; H01L 2224/03912; H01L 2224/0401; H01L 2224/05022; H01L 2224/05023; H01L 2224/05124; H01L 2224/05139; H01L 2224/05147; H01L 2224/05184; H01L 2224/05556; H01L 2224/05568; H01L 2224/05572; H01L 2224/05647; H01L 2224/05666; H01L 2224/1145; H01L 2224/11452; H01L 2224/1146; H01L 2224/1147; H01L 2224/13007; H01L 2224/13021; H01L 2224/13023; H01L 2224/1308; H01L 2224/13082; H01L 2224/13111; H01L 2224/13139; H01L 2224/13147; H01L 2224/81191; H01L 2224/81815; H01L 2924/00012; H01L 2924/13091

(57) ABSTRACT

Methods for forming semiconductor structures are provided. The method for forming a semiconductor structure includes forming a metal pad over a first substrate and forming a polymer layer over the metal pad. The method for forming a semiconductor structure further includes forming a seed layer over the metal pad and extending over the polymer layer and forming a conductive pillar over the seed layer. The method for forming a semiconductor structure further includes wet etching the seed layer using an etchant comprising H2O2. In addition, the step of wet etching the seed layer is configured to form an extending portion having a slope sidewall.

### CROSS REFERENCE TO RELATED APPLICATIONS

This application is a Continuation application of U.S. patent application Ser. No. 15/725,535, filed on Oct. 5, 2017, which is a Divisional application of U.S. patent application Ser. No. 14/208,871, filed on Mar. 13, 2014, the entire of which are incorporated by reference herein.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon.

One important driver for increasing performance in a semiconductor device is the higher levels of integration of circuits. This is accomplished by miniaturizing or shrinking device sizes on a given chip. Modern integrated circuits are made up of a great amount of active devices such as transistors and capacitors. These devices are initially isolated from each other, but are later interconnected together to form functional circuits. Typical interconnect structures include lateral interconnections, such as metal lines (wirings), and vertical interconnections, such as vias and contacts. Interconnections are increasingly determining the limits of performance and the density of modern integrated circuits. On top of the interconnect structures, bond pads may be formed and exposed on the surface of the respective chip. Electrical connections are made through bond pads to connect the chip to a package substrate or another die.

However, although existing bond pads have been generally adequate for their intended purposes, as device scaling-down continues, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1F are cross-sectional representations of various stages of forming a semiconductor structure in accordance with some embodiments.

FIG. 2 is an enlarged drawing of a portion of the semiconductor structure shown in FIG. 1E in accordance with some embodiments.

FIG. 3A is a cross-sectional representation of a semiconductor structure having a seed layer in accordance with some embodiments.

FIG. 3B is an enlarged diagram of a portion of the semiconductor structure shown in FIG. 3A in accordance with some embodiments.

FIG. 4 is a cross-sectional representation of a semiconductor structure having a seed layer in accordance with some embodiments.

FIGS. 5A and 5B are cross-sectional representations of semiconductor packages including the seed layer shown in FIG. 1F in accordance with some embodiments

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

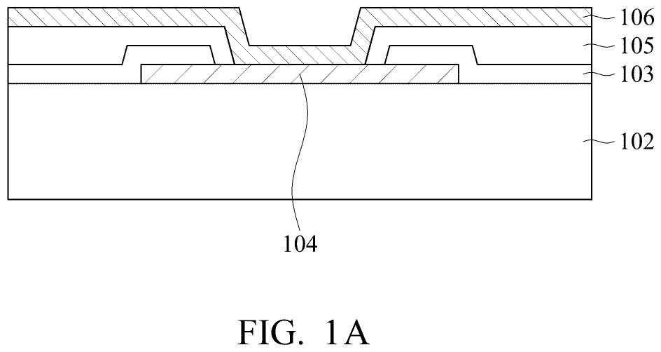

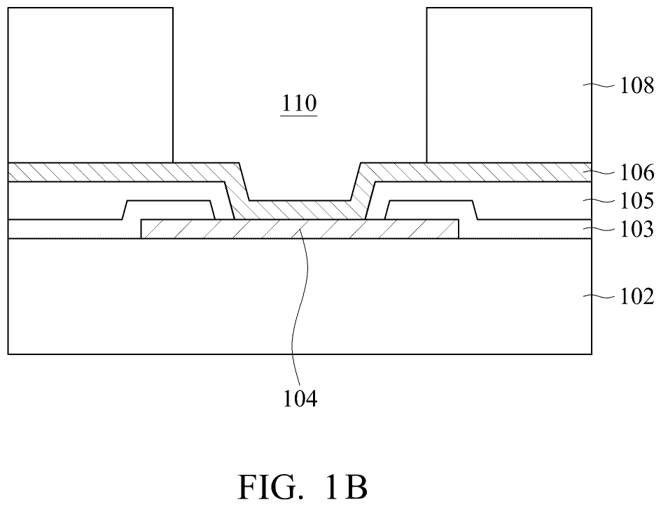

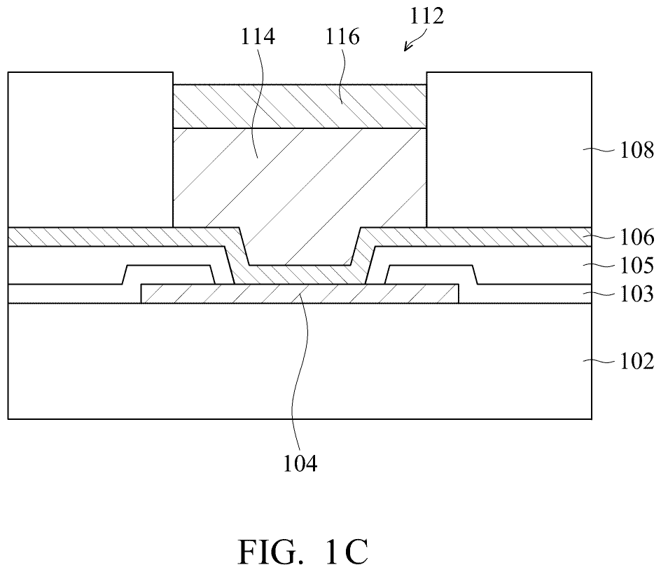

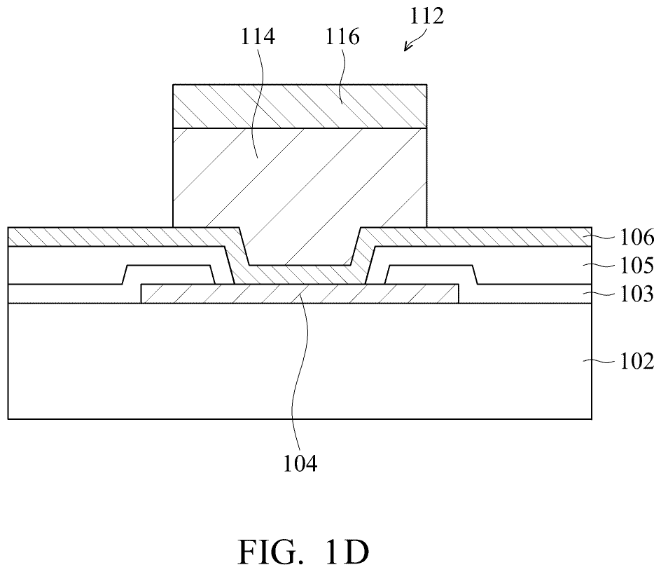

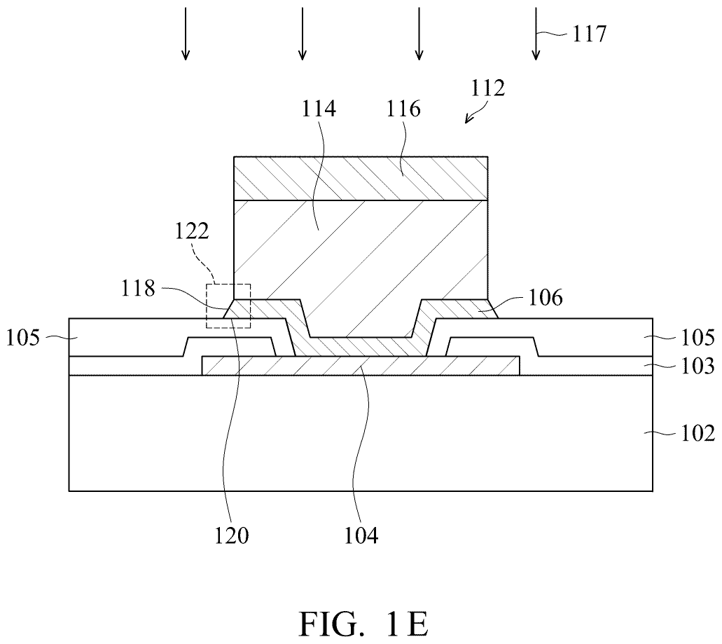

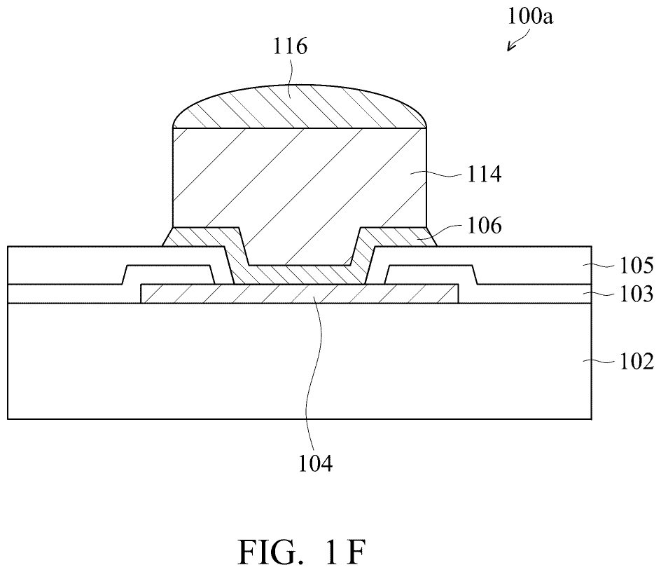

Embodiments for forming a semiconductor structure are provided in accordance with some embodiments of the disclosure. The semiconductor structure may include a seed layer and a conductive pillar formed over the seed layer. FIGS. 1A to 1F are cross-sectional representations of various stages of forming a semiconductor structure 100a in accordance with some embodiments.

Referring to FIG. 1A, a substrate 102 is provided in accordance with some embodiments. Substrate 102 may be included in a semiconductor chip. Substrate 102 may include one of a variety of types of semiconductor substrates employed in semiconductor integrated circuit fabrication, and integrated circuits may be formed in and/or upon substrate 102. Substrate 102 may be a silicon substrate. Alternatively or additionally, substrate 102 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP.

In addition, substrate 102 may further include a plurality of isolation features, such as shallow trench isolation (STI) features or local oxidation of silicon (LOCOS) features. The isolation features isolate various microelectronic elements formed in and/or upon substrate 102. Examples of the types of microelectronic elements formed in substrate 102 include, but are not limited to, transistors such as metal oxide semiconductor field effect transistors (MOSFETs), complementary metal oxide semiconductor (CMOS) transistors, bipolar junction transistors (BJTs), high voltage transistors, high frequency transistors, p-channel and/or n-channel field effect transistors (PFETs/NFETs), resistors, diodes, capacitors, inductors, fuses, and/or other applicable elements.

Various processes may be performed to form the various microelectronic elements, including but not limited to one or more of deposition, etching, implantation, photolithography, annealing, and other applicable processes. The microelectronic elements may be interconnected to form the integrated circuit device, including logic devices, memory devices (e.g., SRAM), radio frequency (RF) devices, input/output (I/O) devices, system-on-chip (SoC) devices, or other applicable devices.

Furthermore, substrate 102 may further include an interconnection structure overlying the integrated circuits. The interconnection structure may include inter-layer dielectric layers and a metallization structure overlying the integrated circuits. The inter-layer dielectric layers in the metallization structure may include low-k dielectric materials, un-doped silicate glass (USG), silicon nitride (SiN), silicon oxynitride (SiON), or other commonly used materials. Metal lines in the metallization structure may be made of copper, copper alloys, or other applicable conductive material.

A metal pad 104 (e.g. metal layer) is formed over substrate 102, as shown in FIG. 1A in accordance with some embodiments. In some embodiments, metal pad 104 is made of conductive materials such as aluminum (Al), copper (Cu), tungsten (W), AlCu alloys, silver (Ag), or other applicable conductive materials. Metal pad 104 may be formed by chemical vapor deposition (CVD), physical vapor deposition (PVD), or other applicable techniques. In addition, metal pad 104 may be a portion of conductive routes in substrate 102 and may be configured to provide an electrical connection upon which a bump structure may be formed for facilitating external electrical connections.

A passivation layer 103 is formed over substrate 102 and has an opening to expose a portion of metal pad 104, as shown in FIG. 1A in accordance with some embodiments. Passivation layer 103 may be made of dielectric materials, such as silicon nitride, silicon oxynitride, silicon oxide, or un-doped silicate glass (USG). Passivation layer 103 may be formed by chemical vapor deposition (CVD), physical vapor deposition (PVD), atomic layer deposition (ALD), high density plasma CVD (HDPCVD), metal organic CVD (MOCVD), plasma enhanced CVD (PECVD), or a thermal process such as a furnace deposition.

In addition, a polymer layer 105 is formed over passivation layer 103, as shown in FIG. 1A in accordance with some embodiments. Polymer layer 105 also exposes a portion of metal pad 104. Polymer layer 105 may be made of materials such as polyimide, epoxy, benzocyclobutene (BCB), polybenzoxazole (PBO), or the like, although other relatively soft, often organic, dielectric materials may also be used. Polymer layer 105 may be formed by CVD, PVD, or other applicable techniques. It should be noted that although passivation layer 103 and polymer layer 105 are shown in FIG. 1A, the formation of passivation layer 103 and polymer layer 105 are optional. Therefore, in some other embodiments, passivation layer 103 and polymer layer 105 are not formed.

Afterwards, a seed layer 106 is formed over substrate 102 to cover metal pad 104, as shown in FIG. 1A in accordance with some embodiments. In some embodiments, seed layer 106 is made of conductive materials such as TiW, TiCu, Cu, CuAl, CuCr, CuAg, CuNi, CuSn, CuAu, or the like. Seed layer 106 may be formed of PVD, sputtering, or other applicable techniques. In some embodiments, seed layer 106 has a thickness in a range from about 0.05 μm to about1 μm. When the thickness of seed layer 106 is too low, the conductivity may not be good enough. On the other hand, when the thickness of seed layer 106 is too great, the cost of forming semiconductor structure 100a may increase.

In addition, seed layer 106 may be one formed of one single layer or multiple layers. In some embodiments, seed layer 106 includes a number of conductive layers, and at least one of the conductive layers is made of TiW.

A photoresist layer 108 is formed over seed layer 106, as shown in FIG. 1B in accordance with some embodiments. Photoresist layer 108 includes an opening 110 over metal pad 104, such that a portion of seed layer 106 over metal pad 104 is exposed by opening 110. In some embodiments, opening 110 in photoresist layer 108 is formed by patterning photoresist layer 108 by photolithography using photo masks.

After photoresist layer 108 is formed, a bump structure 112 is formed in opening 110 of photoresist layer 108, as shown in FIG. 1C in accordance with some embodiments. Bump structure 112 includes a conductive pillar 114 formed on seed layer 106 over metal pad 104 and a solder layer 116 formed over conductive pillar 114.

More specifically, a metallic material is formed in opening 110 to form conductive pillar 114 in accordance with some embodiments. In some embodiments, the metallic material includes pure elemental copper, copper containing unavoidable impurities, and/or copper alloys containing minor amounts of elements such as tantalum (Ta), indium (In), tin (Sn), zinc (Zn), manganese (Mn), chromium (Cr), titanium (Ti), germanium (Ge), strontium (Sr), platinum (Pt), magnesium (Mg), aluminum (Al), or zirconium (Zr).

Conductive pillar 114 may be formed by sputtering, printing, electroplating, electro-less plating, electrochemical deposition (ECD), molecular beam epitaxy (MBE), atomic layer deposition (ALD), and/or commonly used CVD methods. In some embodiments, conductive pillar 114 is formed by electro-chemical plating (ECP).

Next, a solder layer 116 is formed over conductive pillar 114, as shown in FIG. 1C in accordance with some embodiments. In some embodiments, a solder material is formed on conductive pillar 114 to form solder layer 116 in opening 110. In some embodiments, the solder material includes Sn, Ag, Cu, or a combination thereof. In some embodiments, the solder material is a lead-free material. Solder layer 116 may be formed by electroplating, chemical plating, or other applicable processes.

After bump structure 112 is formed, photoresist layer 108 is removed, as shown in FIG. 1D in accordance with some embodiments. Photoresist layer 108 may be stripped by using organic strippers, wet inorganic strippers (oxidizing-type strippers), or dry etching using plasma etching equipment. As shown in FIG. 1D, a portion of seed layer 106 is exposed after photoresist layer 108 is removed.

Next, a wet etching process 117 is performed to the portion of seed layer 106 not covered by conductive pillar 114, as shown in FIG. 1E in accordance with some embodiments. In some embodiments, wet etching process 117 includes using an etchant including H₂O₂. In some embodiments, the concentration of H₂O₂ used during wet etching process 117 is in a range from about 5 wt% to about 70 wt%. In some embodiments, wet etching process 117 is performed at a temperature in a range from about 20° C to about 80° C.

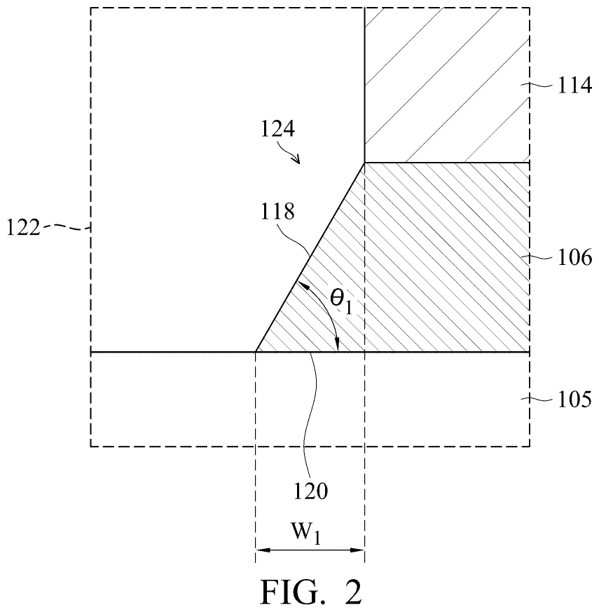

Generally, a wet etching process is an isotropic etching process. Therefore, when a wet etching process is used to remove the seed layer which is not covered by the conductive pillar, a portion of the seed layer below the conductive pillar also tends to be removed to form a concave at the sidewall of the seed layer below the conductive pillar. However, the formation of the concave of the seed layer will induce more stress on inter-metal dielectric layer under the seed layer, due to there are the same chip warpage induced force, but lower area to divide. Accordingly, in accordance with some embodiments of the disclosure, the etchant used in wet etching process 117 is adjusted, such that seed layer 106 under conductive pillar 114 will not be removed, and the concave will not be formed at the sidewall of seed layer 106 during wet etching process 117, as shown in FIG. 2 in accordance with some embodiments.

FIG. 2 is an enlarged drawing of a portion 122 of semiconductor structure 100a shown in FIG. 1E in accordance with some embodiments. As shown in FIG. 2, seed layer 106 has a sidewall 118 and a bottom surface 120, and an angle θ₁ between sidewall 118 and bottom surface 120 of seed layer 106 is in a range from about 20° to about 90°. That is, seed layer 106 below conductive pillar 114 is not etched by wet etching process 117, and therefore seed layer 106has a relative large size. Accordingly, the stress is distributed in the relative large size, and the stress on the inter-metal dielectric layer formed in substrate 102 under conductive pillar 114 will be smaller per unit volume. When angle θ₁ is too great, the concave may be formed and the average stress on seed layer 106 increases. When angle θ₁ is too small, a great amount of the seed layer is left on polymer layer 105 and the risk of an electrical short occurring between bump structure 112 and another bump structure formed adjacent to bump structure 112 increases.

In some embodiments, seed layer 106 further includes an extending portion 124 extending from conductive pillar 114. As shown in FIG. 2, extending portion 124 of seed layer 106 does not overlap with conductive pillar 114. In some embodiments, extending portion 124 is in a shape of a triangle. The triangle extending portion 124 helps release the stress in conductive pillar 114 and improve the distribution of the stress in semiconductor structure 100a in accordance with some embodiments.

In some embodiments, angle θ₁ between sidewall 118 and bottom surface 120 is in a range from about 20° to about 85°. In some embodiments, angle θ₁ between sidewall 118 and bottom surface 120 is in a range from about 20° to about 40°. In some embodiments, angle θ₁ between sidewall 118 and bottom surface 120 is in a range from about 40° to about 60°. In some embodiments, angle θ₁ between sidewall 118 and bottom surface 120 is in a range from about 60° to about 80°.

In some embodiments, extending portion 124 has a width W₁ in a range from about 0.05 μm to about 3 μm. Formation of extending portion 124 of seed layer 106 enables the distribution of the stress in semiconductor structure 100a to be improved.

After wet etching process 117 is performed, solder layer 116 is reflowed by a reflowing process, as shown in FIG. 1F in accordance with some embodiments. As shown in FIG. 1F, after the reflowing process is performed, solder layer 116 has a spherical top surface.

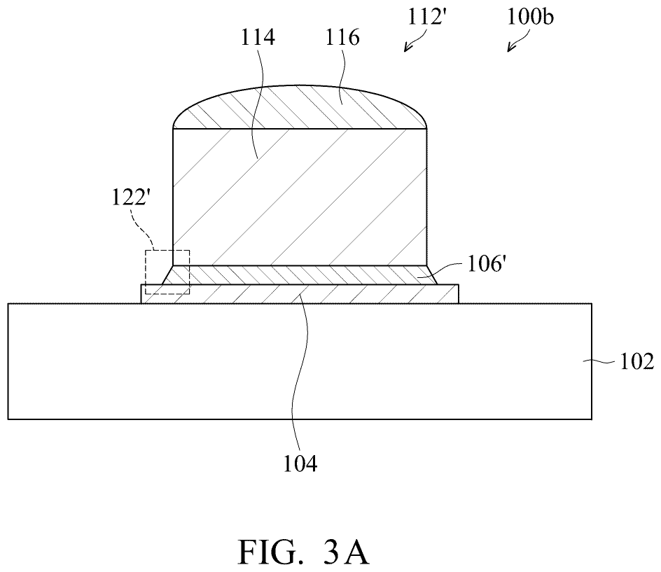

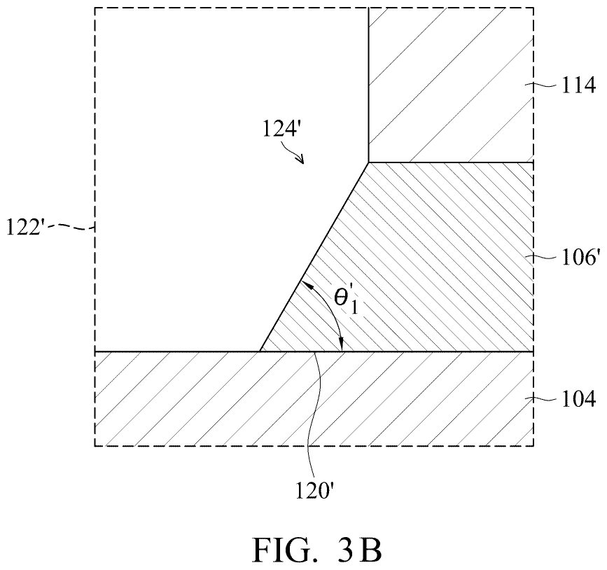

FIG. 3A is a cross-sectional representation of a semiconductor structure 100b having a seed layer 106′ in accordance with some embodiments. FIG. 3B is an enlarged diagram of a portion 122′ of semiconductor structure 100b shown in FIG. 3A in accordance with some embodiments. Semiconductor structure 100b having seed layer 106′ is similar to semiconductor structure 100a having seed layer 106 shown in FIG. 1F except passivation layer 103 and polymer layer 105 are not formed in semiconductor structure 100b. Processes and materials for forming semiconductor structure 100b are similar to those for forming semiconductor structure 100a and are not repeated herein.

More specifically, metal layer 104 is formed over substrate 102, and seed layer 106′ is formed over metal layer 104, as shown in FIG. 3A in accordance with some embodiments. Afterwards, bump structure 112′ including conductive pillar 114 and solder layer 116 are formed over seed layer 106′. Since passivation layer 103 and polymer layer 105 are not formed in semiconductor structure 100b, seed layer 106′ is directly formed over metal layer 104.

As shown in FIG. 3B, seed layer 106′ also has a sidewall 118′ and a bottom surface 120′, and an angle θ₁′ between sidewall 118′ and bottom surface 120′ is the same as, or similar to, angle θ₁ shown in FIG. 2. For example, angle θ₁′ is in a range from about 20° to about 90°.

In addition, seed layer 106′ also includes an extending portion 124′ in accordance with some embodiments. In some embodiments, extending portion 124′ has a width similar to width W₁ in a range from about 0.05 μm to about 3 μm. In addition, extending portion 124′ of seed layer 106′ formed over metal layer 104 can also improve the distribution of the stress in semiconductor structure 100b.

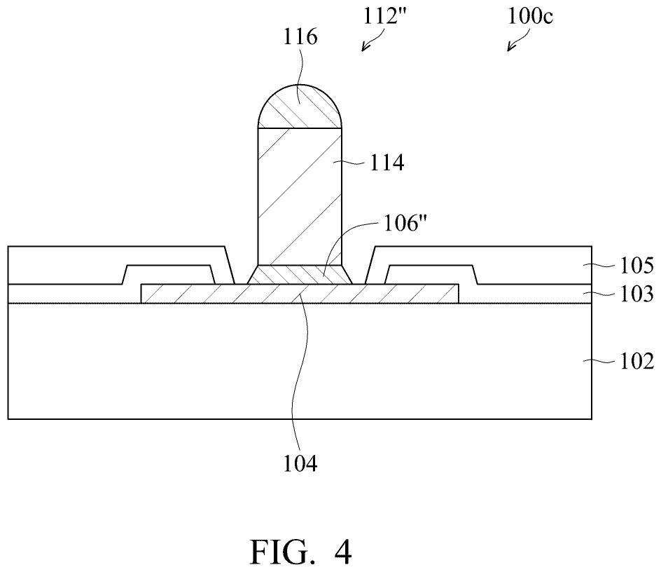

FIG. 4 is a cross-sectional representation of a semiconductor structure 100c having a seed layer 106″ in accordance with some embodiments. Semiconductor structure 100c having seed layer 106″ is similar to semiconductor structure 100a having seed layer 106 shown in FIG. 1F except seed layer 106″ and bump structure 112″ are formed in the opening of polymer layer 105. Processes and materials for forming semiconductor structure 100c are similar to those for forming semiconductor structure 100a and are not repeated herein.

More specifically, metal layer 104 is formed over substrate 102, and passivation layer 103 and polymer layer 105 are formed over substrate 102 and cover the ends of metal layer 104, as shown in FIG. 4 in accordance with some embodiments. In addition, polymer layer 105 has an opening to expose a center portion of metal layer 104, and seed layer 106″ and bump structure 112″ are formed in the opening without overlapping with passivation layer 103 and polymer layer 105.

Bump structure 112″ includes conductive pillar 114 and solder layer 116 formed over conductive pillar 114 in accordance with some embodiments. Seed layer 106″ formed over metal pad 104 without overlapping with passivation layer 103 and polymer layer 105 can also improve the distribution of the stress in semiconductor structure 100c.

After the semiconductor structure, such as semiconductor structures 100a, 100b, or 100c, is formed, substrate 102 (e.g. a semiconductor chip) may be attached to another substrate, such as a dielectric substrate, a package substrate, a printed circuit board (PCB), an interposer, a wafer, another chip, a package unit, or the like. For example, embodiments may be used in chip-to-substrate bonding configuration, a chip-to-chip bonding configuration, a chip-to-wafer bonding configuration, a wafer-to-wafer bonding configuration, chip-level packaging, wafer-level packaging, or the like.

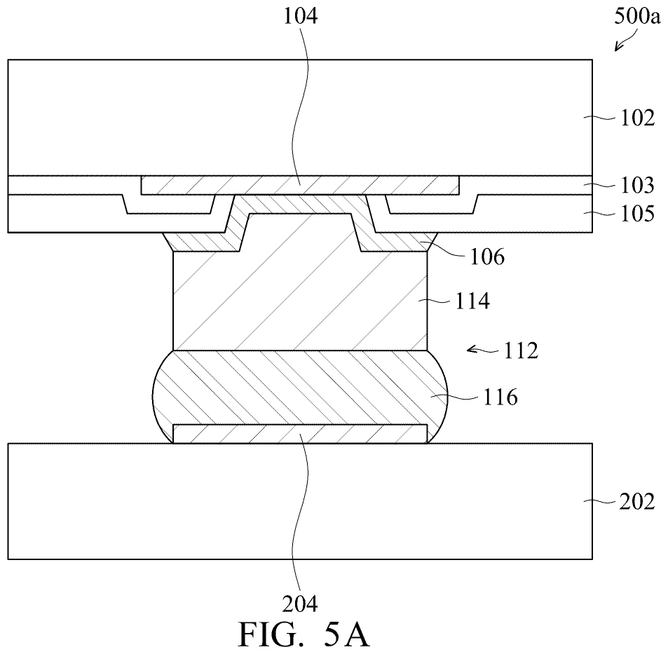

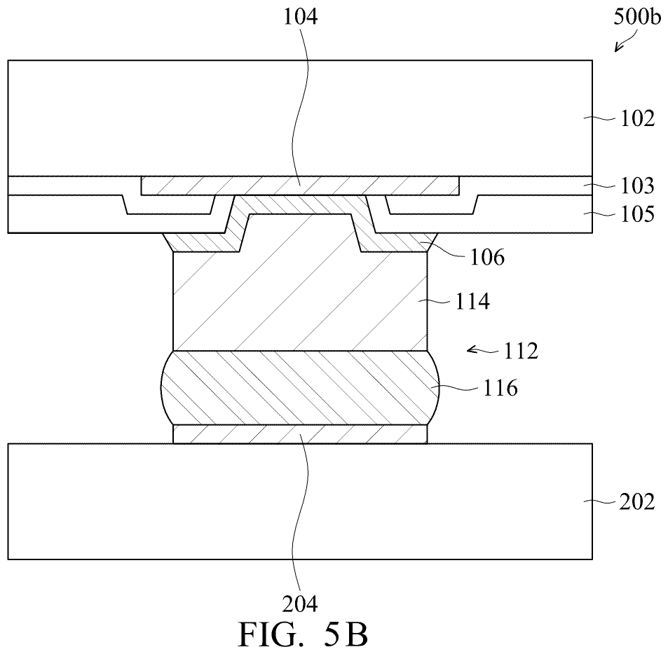

FIG. 5A is a cross-sectional representation of a semiconductor package 500a including seed layer 106 shown in FIG. 1F in accordance with some embodiments. Bump structure 112 formed on seed layer 106 over substrate 102 is bonded to a conductive feature 204 formed over a second substrate 202 in accordance with some embodiments. In some embodiments, bump structure 112 and conductive feature 204 are bonded through solder layer 116, such as by a reflow process. Therefore, the sidewalls of conductive feature 204 may be covered by solder layer 116, as shown in FIG. 5A.

In some embodiments, substrate 102 is a semiconductor chip, and substrate 202 is a package substrate. In some embodiments, conductive feature 204 is a metal trace, and therefore a bump-on-trace (BOT) interconnect is formed in semiconductor package 300.

FIG. 5B is a cross-sectional representation of a semiconductor package 500b including seed layer 106 shown in FIG. 1F in accordance with some embodiments. Semiconductor package 500b is similar to semiconductor package 500a except substrate 102 and substrate 202 are bonded by a heat-press bonding process.

More specifically, bump structure 112 and conductive feature 204 are bonded by heat-press bonding. Therefore, solder layer 116 will not flow to the sidewalls of conductive feature 204.

As described previously, if a seed layer formed below a conductive pillar is etched during a wet etching process, a concave will be formed from the sidewall of the seed layer. The concave may result in the stress in the conductive pillar being focus on a relatively small area, such that the dielectric layer below (e.g. the extreme-low-k dielectric layer formed in the substrate) tends to become cracked or broken. In addition, the effective area of the seed layer decreases.

Accordingly, the seed layer described in various embodiments, such as seed layers 106, 106′, and 106″, are formed by wet etching process 117, which is adjusted not to etch the seed layer below conductive pillar 114. Therefore, no concave will be formed from the sidewall of the seed layer even though a wet etching process is performed. In addition, an extending portion, such as extending portion 124, is formed to extend from the sidewall of conductive pillar 114 in accordance with some embodiments. Therefore, the effective area of the seed layer increases. Furthermore, the stress in conductive pillar 114 can be released to substrate 102 more evenly to prevent the dielectric layer in substrate 102 from breaking or cracking.

Embodiments for forming a semiconductor structure having a seed layer are provided. The seed layer is positioned between a metal pad and a conductive pillar. In addition, the seed layer below the conductive pillar is not etched during a wet etching process used to remove the excess seed layer material. Therefore, no concave is formed at the sidewall of the seed layer below the conductive pillar. As a result, the distribution of the stress in the semiconductor structure is improved. In addition, the effective area of the seed layer increases.

In some embodiments, a method for forming a semiconductor structure is provided. The method for forming a semiconductor structure includes forming a metal pad over a first substrate and forming a polymer layer over the metal pad. The method for forming a semiconductor structure further includes forming a seed layer over the metal pad and extending over the polymer layer and forming a conductive pillar over the seed layer. The method for forming a semiconductor structure further includes wet etching the seed layer using an etchant comprising H₂O₂. In addition, the step of wet etching the seed layer is configured to form an extending portion having a slope sidewall.

In some embodiments, a method for forming a semiconductor structure is provided. The method for forming a semiconductor structure includes forming a metal pad over a first substrate and forming a polymer layer covering the metal pad. The method for forming a semiconductor structure further includes forming a seed layer over the metal pad and extending onto a top surface of the polymer layer and forming a conductive pillar over the seed layer. The method for forming a semiconductor structure further includes forming a solder layer over the conductive pillar and wet etching the seed layer not covered by the conductive pillar so that a sidewall of the seed layer extends outwardly from a bottom of the conductive pillar to the top surface of the polymer layer by using an etchant comprising H₂O_{2.}

In some embodiments, a method for forming a semiconductor structure is provided. The method for forming a semiconductor structure includes forming a metal pad over a first substrate and forming a seed layer to cover the metal pad over the first substrate. The method for forming a semiconductor structure further includes forming a resist layer having an opening over the seed layer and forming a conductive pillar in a bottom portion of the opening and a solder layer in a top portion of the opening. The method for forming a semiconductor structure further includes removing the resist layer and etching the seed layer to form an extending portion having a slope sidewall by using an etchant comprising H₂O₂. In addition, a concentration of H₂O₂ in the etchant is in a range from about 5 wt% to about 70 wt%.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a metal pad over a first portion of a substrate;
forming a passivation layer covering a second portion of the substrate and interfacing with the metal pad;
forming a thinner portion of a polymer layer over the first portion of the substrate and a thicker portion of the polymer layer over the second portion of the substrate, wherein the thinner portion of the polymer layer interfaces with the metal pad while the thicker portion of the polymer layer interfaces with the passivation layer;
forming a seed layer over the metal pad, the thinner portion of the polymer layer, and the thicker portion of the polymer layer;
forming a photoresist layer over the seed layer, wherein the photoresist layer has an opening over the first portion of the substrate and vertically overlapping the thinner portion of the polymer layer;
forming a conductive pillar and a solder layer over the conductive pillar in the opening of the photoresist layer;
using an organic stripper or an inorganic stripper to remove the photoresist layer;
wet etching the seed layer using an etchant comprising about 5 wt% to about 70 wt% of H₂O₂ at a temperature in a range from about 20° C to about 80° C.

2. The method for forming a semiconductor structure as claimed in claim 1, wherein the inorganic stripper is an oxidizing-type stripper.

3. The method for forming a semiconductor structure as claimed in claim 1, wherein a sidewall of the second portion of the substrate, a sidewall of the passivation layer, a sidewall of the thicker portion of the polymer layer are substantially aligned with a sidewall of the photoresist layer before forming the conductive pillar.

4. The method for forming a semiconductor structure as claimed in claim 1, wherein the substrate comprises bipolar junction transistors, high voltage transistors, high frequency transistors, resistors, diodes, capacitors, inductors, or fuses.

5. The method for forming a semiconductor structure as claimed in claim 1, wherein the seed layer comprises a first conductive material layer and a second conductive material layer, and the first conductive material layer and the second conductive material layer are made of different conductive materials.

6. The method for forming a semiconductor structure as claimed in claim 1, wherein the conductive pillar is made of a copper alloy comprising tantalum, indium, tin, zinc, manganese, chromium, titanium, germanium, strontium, platinum, magnesium, aluminum, or zirconium.

7. A method for forming a semiconductor structure, comprising:
forming a metal pad over a first substrate, wherein the first substrate has a first edge at a first side and a second edge at a second side opposite to the first side;
forming a passivation layer having a first sidewall at the first side intersecting a top surface of the metal pad and a second sidewall at the second side aligned with the second edge of the first substrate;
forming a polymer layer having a first sidewall at the first side intersecting the top surface of the metal pad, a second sidewall at the second side aligned with the second edge of the first substrate, and a flat top surface continuously extending between the first sidewall and the second sidewall of the polymer layer;
forming a seed layer covering the metal pad and the polymer layer, wherein the seed layer has a first sidewall at the first side aligned with the first edge of the first substrate and a second sidewall at the second side aligned with the second edge of the first substrate;
forming a photoresist layer with an opening over the seed layer, wherein the photoresist layer has a first sidewall at the first side aligned with the first edge of the first substrate and a second sidewall at the second side aligned with the second edge of the first substrate;
forming a conductive pillar that interfaces with the seed layer in the opening of the photoresist layer;
forming a solder layer that interfaces with the conductive pillar in the opening of the photoresist layer;
removing the photoresist layer; and
partially etching the seed layer using an etchant comprising about 5 wt% to about 70 wt% of H₂O₂ at a temperature in a range from about 20° C to about 80° C, resulting in a third sidewall of the seed layer at the first side is apart from the first edge of the first substrate and a fourth sidewall of the seed layer at the second side is apart from the second edge of the first substrate.

8. The method for forming a semiconductor structure as claimed in claim 7, further comprising:
bonding the first substrate with a second substrate through the solder layer, wherein the second substrate has a first edge at the first side and a second edge at the second side, and the second edge is aligned with the second sidewall of the polymer layer.

9. The method for forming a semiconductor structure as claimed in claim 8, further comprising:
forming a conductive feature over the second substrate, wherein a top surface of the conductive feature is in direct contact with the solder layer.

10. The method for forming a semiconductor structure as claimed in claim 9, wherein an intersection between a sidewall of the conductive feature and a top surface of the second substrate is covered by the solder layer.

11. The method for forming a semiconductor structure as claimed in claim 9, wherein a distance between an intersection of a sidewall of the metal pad and the second edge of the first substrate is smaller than an intersection of a sidewall of the conductive feature and the second edge of the second substrate.

12. The method for forming a semiconductor structure as claimed in claim 7, wherein the metal pad is made of tungsten, AlCu alloys, or silver.

13. The method for forming a semiconductor structure as claimed in claim 7, wherein the seed layer is made of TiCu, Cu, CuAl, CuCr, CuAg, CuNi, CuSn, or CuAu.

14. A method for forming a semiconductor structure, comprising:
forming a metal pad over a first substrate, wherein the metal pad has a first dimension between a first sidewall and a second sidewall in a first direction;
forming a passivation layer over the first substrate and covering the first sidewall and the second sidewall of the metal pad, wherein a central portion of the metal pad is exposed by the passivation layer and has a second dimension in the first direction;
forming a polymer layer covering the passivation layer and partially covering the central portion of the metal pad;
forming a seed layer covering the central portion of the metal pad and the polymer layer;
forming a photoresist layer with an opening over the central portion of the metal pad;
forming a conductive pillar in the opening of the photoresist layer;
forming a solder layer over the conductive pillar in the opening of the photoresist layer, wherein a top surface of the solder layer is lower than a top surface of the photoresist layer, the conductive pillar continuously extends from a top surface of the seed layer to a bottom surface of the solder layer, and an interface between the conductive pillar and the solder layer is higher than a topmost surface of the seed layer in a cross-sectional view;
removing the photoresist layer;
etching the seed layer using an etchant comprising about 5 wt% to about 70 wt% of H₂O₂ at a temperature in a range from about 20° C to about 80° C; and
bonding the solder layer to a conductive feature over a second substrate.

15. The method for forming a semiconductor structure as claimed in claim 14, wherein the conductive feature has a third dimension in the first direction, and the third dimension is smaller than the first dimension and is greater than the second dimension.

16. The method for forming a semiconductor structure as claimed in claim 14, wherein the conductive pillar has a fourth dimension in the first direction, and the fourth dimension is smaller than the first dimension and is greater than the second dimension.

17. The method for forming a semiconductor structure as claimed in claim 14, wherein the polymer layer has a first surface and a second surface completely overlapping with the first surface in a second direction that is different from the first direction, and wherein the first surface has a first slope, a first portion of the second surface has a second slope, a second portion and a fourth portion of the second surface have the first slope, and a third portion has a third slope, and the first slope, the second slope, and the third slope are different.

18. The method for forming a semiconductor structure as claimed in claim 17, wherein the first portion of the second surface of the polymer layer is in direct contact with the metal pad, and the second portion of the second surface of the polymer layer partially overlaps the seed layer.

19. The method for forming a semiconductor structure as claimed in claim 18, wherein the third portion and the fourth portion of the second surface of the polymer layer are laterally spaced apart from the seed layer.

20. The method for forming a semiconductor structure as claimed in claim 18, wherein the second portion of the second surface of the polymer layer is sandwiched between the first portion and the third portion of the second surface of the polymer layer, and the third portion of the second surface of the polymer layer is sandwiched between the second portion and the fourth portion of the second surface of the polymer layer
